(19) United States
(12) Patent Application Publication
(10) Pub. No.: US 2009/0110206 A1
(43) Pub. Date: Apr. 30, 2009

(54) METHOD AND APPARATUS FOR SENSING A SIGNAL ABSENCE OF AUDIO AND AUTOMATICALLY ENTERING LOW POWER MODE

(75) Inventors: John R. Haggis, San Jose, CA (US); Francis Lau, Fremont, CA (US); John Glissman, Manila (PH)

Correspondence Address: STAINBROOK & STAINBROOK, LLP, 412 AVIATION BOULEVARD, SUITE H, SANTA ROSA, CA, 95403, US

(73) Assignee: AERIELLE TECHNOLOGIES, INC., MOUNTAIN VIEW, CA (US)

(21) Appl. No.: 12/348,854

(22) Filed: Jan. 5, 2009

Related U.S. Application Data
(63) Continuation-in-part of application No. 11/680,936, filed on Mar. 1, 2007.
Application No. 11/680,936 is a continuation-in-part of application No. 10/540,070, filed on Jun. 22, 2005, now Pat. No. 7,474,757.
(60) Provisional application No. 60/438,905, filed on Jan. 9, 2003.

(51) Int. Cl. H04R 29/00; H03F 99/00

(52) U.S. Cl. 381/58; 381/120

(57) ABSTRACT

An electronic device having a unique audio sensing method that senses the event of no audio for a predetermined period of time. The sensed information is used by a microprocessor to bring the device into a low-power mode. The same method may be used to bring a device into active mode from a low-power mode.

### CROSS REFERENCES TO RELATED APPLICATIONS

The present application is a continuation-in-part application of U.S. Utility patent application Ser. No. 11/680,936, filed Mar. 1, 2007, which is a continuation-in-part of U.S. Utility patent application Ser. No. 10/540,070, filed Jun. 22, 2005, which is a Section 371 application claiming the benefit of International Patent Application Serial Number PCT/US2004/000452, filed Jan. 9, 2004, which, in turn, claims the benefit of the filing date of U.S. Provisional Patent Application Ser. No. 60/438,905, filed Jan. 9, 2003.

### SEQUENCE LISTING

Not applicable.

### STATEMENT REGARDING FEDERALLY SPONSORED RESEARCH OR DEVELOPMENT

Not applicable.

### THE NAMES OR PARTIES TO A JOINT RESEARCH AGREEMENT

Not applicable.

### INCORPORATION-BY-REFERENCE OF MATERIAL SUBMITTED ON A COMPACT DISC

Not applicable.

### BACKGROUND OF THE INVENTION

1. Field of the Invention

The present invention relates generally to the field of consumer electronics, and, more specifically, to the field of electronic audio devices having an auto-off function. Still more particularly, the present invention relates to a method of automatically entering a low power state in such electronic devices by sensing inactivity using various forms of sensing technology. The device may also automatically turn on once again by means of sensing activity from the same or different sensor.

2. Discussion of Related Art Including Information Disclosed Under 37 CFR § 1.97, 1.98

With the widespread use of portable AM/FM receivers, cassette, CD, MP3 players, as well as other consumer electronic devices outputting audio and/or data signals, a need has arisen for more convenient methods for delivering those signals to the system user. Currently, users typically wear headphones that are coupled to the signal-generating device by wires. These wires are inconvenient and possibly dangerous. In the case of portable audio devices, for instance, the devices may be employed while their users are doing other things such as jogging, rollerblading, manual labor, driving, etc. During such activities, wires are susceptible to being tangled up or otherwise providing a hindrance to efficient use. The same is true of wires leading from stationary devices such as a personal computer, car dashboard, or rack mounted stereo.

Therefore, as signal generating devices have proliferated, so too has the need to make them convenient. One example of a convenient, hands-free environment was disclosed in U.S. Pat. No. 5,771,441 for a Small Battery Operated RF Transmitter for Portable Audio Devices for Use with Headphones with Rf Receiver, issued Jun. 23, 1998 to John E. Alstatt (hereinafter referred to as “Alstatt”).

In Alstatt, there is taught a portable RF transmitter that modulates audio signals from an audio source onto an FM carrier and then transmits such signals to an FM receiver mounted on a headset worn by a user. The RF transmitter uses its own ground circuit and the ground circuit of the audio source as two elements of a short dipole. Products, such as the AUDIOBUG®, available from Aerielle, Inc. of Mountain View, Calif., have successfully embodied such a wireless device.

A further example of a solution to the problem of wireless transmission is found where small RF transmitters have been used on electric guitars to transmit audio signals from the guitar transducer to a receiver coupled to a power amplifier. An example of this type of technology is found in U.S. Pat. No. 5,025,704 for a Cordless Guitar Transmitter, issued Jun. 26, 1991 to Richard L. Davis (hereinafter referred to as “Davis”). In Davis, there is taught an electronic device which, when connected to an electric guitar, or other similar stringed instrument, will effect wireless transmission over a selectable frequency of the FM broadcast band. The unit is compact as it uses the metal strings of the guitar as a partial antenna. The unit remains stationary after being plugged into the guitar's input receptacle, and no transmitting portion of the device has to be attached to the musician's belt or guitar strap, or to the musician's person. Furthermore, no antenna extends from the device itself. The device is automatically turned on when plugged in.

As devices providing wireless transmission capabilities have improved and become more convenient and accessible at the consumer level, there has also grown a need to eliminate the transmission of unmodulated RF carriers, and to become more efficient in prolonging battery life. Without this efficiency, larger and/or more expensive batteries, or multiple batteries coupled together, are required to drive the transmitters. The alternative has been a drastically reduced battery life. Thus, there has evolved a need for circuits that reduce battery consumption.

Several United States patents reflect proposed solutions to this need, including U.S. Pat. No. 5,636,077, to Kim, which discloses a video recording and reproduction device having an automatic power-saving circuit. The circuit determines the existence of an input video signal and controls system functions accordingly. Video recording and reproduction functions continue if an input video signal is present, and, if no video signal exists and no function key is input for a predetermined period of time, the recording/reproducing actions are halted and power is automatically cut-off.

U.S. Pat. No. 6,441,804, to Hsien, teaches a wireless cursor control system that includes a pointing device and a receiver. The pointing device has a controller for receiving user input and for providing a control signal, and a transmitter that includes an antenna and a high frequency modulator coupled to the controller for receiving the control signal and for generating an output signal for transmission via the antenna. The high frequency modulator includes a variable frequency modulator circuit for selectively changing the frequency deviation of the control signal, and a high frequency circuit for increasing the frequency deviation of the control signal to produce the output signal. The receiver has an antenna that receives the output signal, and a demodulation circuit for demodulating the received output signal. The transmitter circuit includes a power saving circuit coupled to the high frequency modulator and controller and detects whether controller has received any input from a button circuit. If no input has been received by the controller for a predetermined time period, the power saving circuit automatically switches the transmitter into a power-saving mode by disconnecting the RF amplifier and the buffer circuit. In the power-saving mode, the button circuit, clock generator, and controller are on, and the remaining circuits are deactivated. User activation of any of the buttons of the button circuit causes the transmitter to come out of the power-saving mode.

U.S. Pat. No. 6,529,067 to Uen shows a power saving device for a wireless pointer including a first resistor, a second capacitor, a signal generation circuit, a bias control circuit including an n-type channel MOSFET having a drain connected to the signal generation circuit at a second node for driving the signal generation circuit, a switch having one end connected to an n-type channel MOSFET gate at a first node, a semiconductor having an anode connected to the first node gate and a cathode connected to the positive terminal of the power source, and a first capacitor in series connection with the semiconductor means. When the wireless pointer is inoperative, the switch opens automatically to cause the leakage current of the reverse biased semiconductor to charge the first capacitor. When the switch is closed, the first capacitor discharges completely and cuts off the n-type channel MOSFET. The charging and discharging decrease current consumption in a standby mode.

U.S. Pat. No. RE 37,884 to Chen discloses a transmitter-receiver system including a transmitter unit installed in an audio equipment, and a receiver unit installed in an earphone, wherein the transmitter unit includes an automatic electric level regulator to regulate the electric level of the output signal of audio equipment to a predetermined range, a power control circuit controlled by the output signal of the audio equipment to provide the necessary working voltage, and an inductance antenna to transmit output signal from the audio equipment to the receiver unit. The receiver unit is of low working voltage design, including an automatic 24-time frequency divider circuit to effectively discriminate left and right sound tracks, and an auto-shut off circuit to automatically cut off power supply when the audio equipment does no work. The transmitter unit and the receiver unit further use a respective dual oscillation frequency regulating circuit consisting of an oscillating transistor, a dielectric resonator, and two variable resistors for regulating the range of the frequency.

Thus, it will be appreciated that many consumer electronic devices now employ some kind of automatic off or sleep mode option, in which the user may set 0, 30, 60, or 90 minutes until the unit automatically shuts off after the set time. Most of the contemporary devices employ a simple timer to count a set time before the unit will power off, regardless of any kind of activity. An example would be an alarm clock or TV with a sleep mode option.

In other cases, the electronic device may automatically turn off after a set time of inactivity in which the unit's primary function is not in use. Examples include such devices as DVD players, which may turn off if a predetermined amount of time has passed in which a DVD has not been played. Another definition of inactivity may include the absence of user input for a period of time, either to a remote control for the device or to the device itself.

It is important to note that the motivation driving the implementation of automatic sleep modes is to save power, which also serves to prolong the life of the device. Sleep modes are also important in reducing RF pollution by turning off unused RF transmitters, if any are employed in an electronic device.

In terms of power savings, the ideal is to consume as close to 0 watts as possible while in the power-off mode. In part, this is owing to the increasing concern for global stand-by power of electronic devices. In a modern battery powered device, power is generally not cut off by a mechanical switch, since a “soft” button is the preferred user interface. A soft button requires some minimal level of logic to be active in order to sense the power-on event after power-off. Hence, even in power-down mode, a minimal level of battery-power may be used on the order of tens of micro amps.

The foregoing prior art references and products reflect the current state of the art of which the present inventors are aware. Reference to, and discussion of, these patents is intended to aid in discharging Applicants' acknowledged duty of candor in disclosing information that may be relevant to the examination of claims to the present invention. However, it is respectfully submitted that none of the above-indicated patents disclose, teach, suggest, show, or otherwise render obvious, either singly or when considered in combination, the invention described and claimed herein.

### BRIEF SUMMARY OF THE INVENTION

The present invention is a novel method and apparatus by which an electronic device will determine a state of inactivity via sampling audio levels, thereby powering off the device when a sufficiently lengthy period of time with audio inactivity has passed, and also powering on the device when it senses audio activity. The essence of the invention is to power on or off the device using novel methods by sensing activity or inactivity.

It is therefore an object of the present invention to provide a new and improved circuit with an auto-off/auto-on capability for an audio device.

It is another object of the present invention to provide a new and improved circuit that also includes a power-saving auto-off capability.

A further object or feature of the present invention is a new and improved circuit and method for providing a combination of auto-off and/or auto-on capabilities for a wireless transmitter.

An even further object of the present invention is to provide a novel circuit having auto-off and/or auto-on capabilities for a wireless transmitter that reduces unnecessary RF transmissions generated by the circuit.

Accordingly, an aspect of the present invention is the reduction of battery consumption in an audio device by providing an auto-off circuit that will automatically switch off the system when it is not in use.

An additional aspect of the present invention is the ability to activate the system by providing an auto-on capability.

Other novel features which are characteristic of the invention, as to organization and method of operation, together with further objects and advantages thereof will be better understood from the following description considered in connection with the accompanying drawings, in which a preferred embodiment of the invention is illustrated by way of example. It is to be expressly understood, however, that the drawings are for illustration and description only and are not intended as a definition of the limits of the invention. The various features of novelty which characterize the invention are pointed out with particularity in the claims annexed to and forming part of this disclosure. The invention resides not in any one of these features taken alone, but rather in the particular combination of all of its structures and elements for the functions specified.

The foregoing summary broadly sets out the more important features of the present invention so that the detailed description that follows may be better understood, and so that the present contributions to the art may be better appreciated. There are additional features of the invention that will be described in the detailed description of the preferred embodiments of the invention which will form the subject matter of the claims appended hereto.

Accordingly, before explaining the preferred embodiment of the disclosure in detail, it is to be understood that the disclosure is not limited in its application to the details of the construction and the arrangements set forth in the following description or illustrated in the drawings. The inventive method and apparatus described herein is capable of other embodiments and of being practiced and carried out in various ways.

As such, those skilled in the art will appreciate that the conception, upon which this disclosure is based may readily be used as a basis for designing other structures, methods, and systems for carrying out the several purposes of the present invention. It is important, therefore, that the claims are regarded as including such equivalent constructions as far as they do not depart from the spirit and scope of the present invention. Rather, the fundamental aspects of the invention, along with the various features and structures that characterize the invention, are pointed out with particularity in the claims annexed to and forming a part of this disclosure. For a better understanding of the present invention, its advantages and the specific objects attained by its uses, reference should be made to the accompanying drawings and descriptive matter in which there are illustrated the preferred embodiments.

### BRIEF DESCRIPTION OF THE SEVERAL VIEWS OF THE DRAWINGS

The invention will be better understood and objects other than those set forth above will become apparent when consideration is given to the following detailed description thereof. Such description makes reference to the annexed drawings wherein:

FIG. 1 is a perspective drawing of the supporting structure of a device that can utilize the present invention;

FIG. 2 partitioned into FIGS. 2A-2D for clarity) is a circuit diagram of an audio transmitter having an auto-off and/or auto-on circuit as used in the present invention;

FIG. 3 (partitioned into FIGS. 3A-3D for clarity) is a circuit diagram of an alternative embodiment of a circuit employed in the present invention, wherein a comparator detects the presence of audio, and wherein an embedded controller detects the output of the comparator, and provides an additional timing function for extending the duration of transmission in the absence of audio in the auto-off circuit;

FIG. 4 partitioned into FIGS. 4A-4D) is a circuit diagram of an alternative embodiment of a circuit employed in the present invention, wherein an embedded controller provides a timing function for the auto-off circuit, and detects the presence of audio;

FIG. 5 is a graph showing the A/D converter sampling duration for the audio signal;

FIG. 6 is a schematic circuit diagram showing the audio sensing unit of the present invention; and

FIG. 7 is a schematic flow chart showing the basic logic employed in the apparatus software to flag an auto-off event.

### DETAILED DESCRIPTION OF THE INVENTION

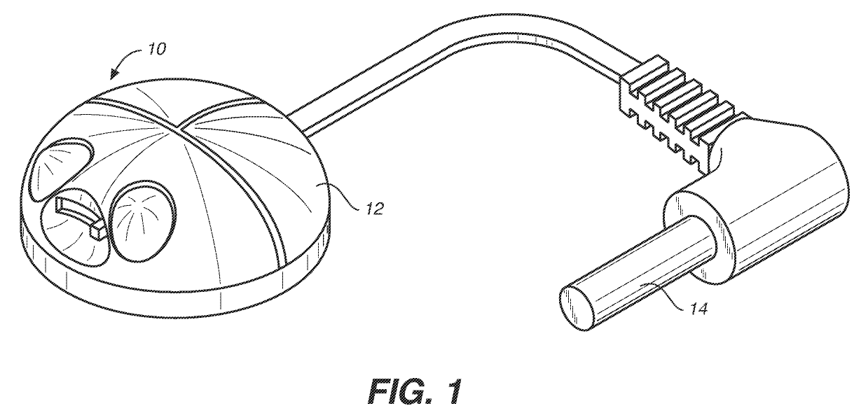

Referring first to FIG. 1, there is shown a perspective drawing of the supporting structure or device that can utilize the present invention. A battery operated audio source, typically a portable stereo radio, a portable cassette player, a portable compact disk player, or a digital MP3 player, generates audio signals from received radio signals or program material recorded on a medium. These audio signals are presented at a headphone or output jack which, in turn, are electrically connected to the RF transmitter 10.

The portable, battery operated RF transmitter 10, is comprised of a transmitter housing 12 and enclosed integrated circuitry and a male plug 14, which plugs into the headphone or output jack of the audio source. The RF transmitter 10 could alternatively be hardwired to, or embedded in, the device as well. The audio signals generated by the audio source are amplified at the audio transmitter 10 and modulate an RF carrier. The RF carrier is coupled to an antenna for radiation to a remote receiver.

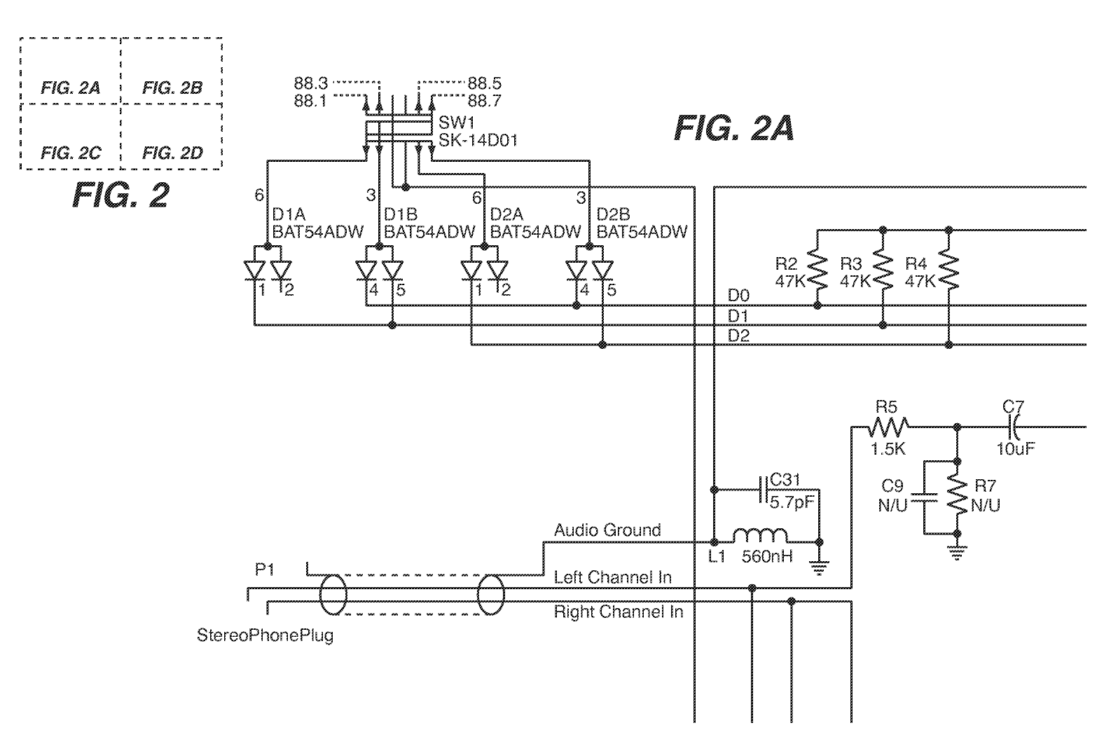

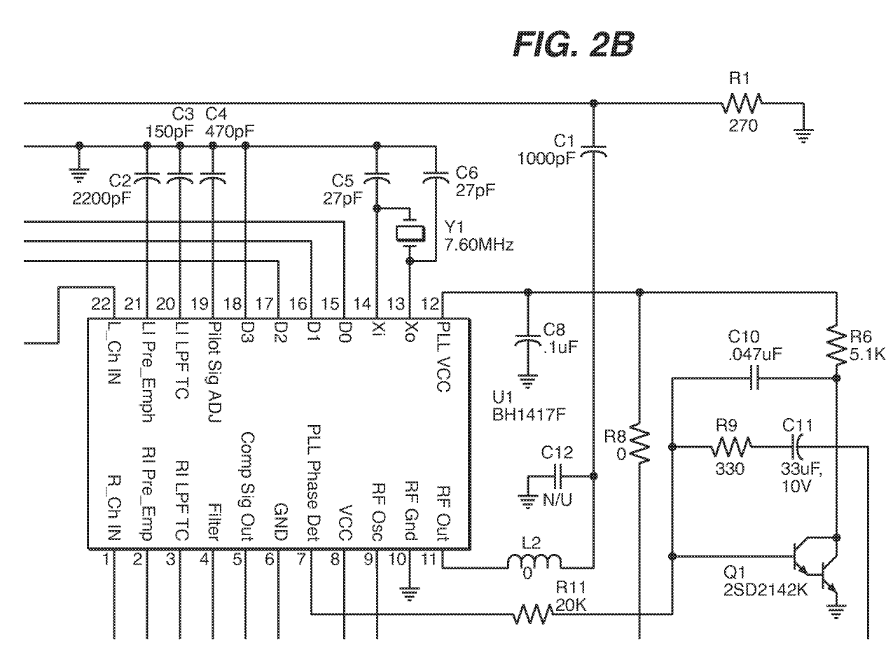

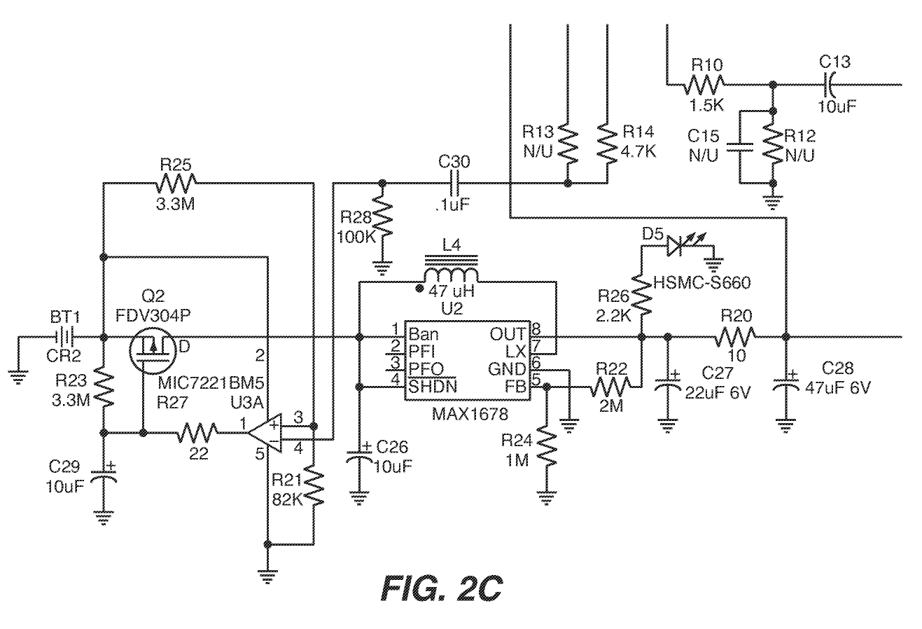

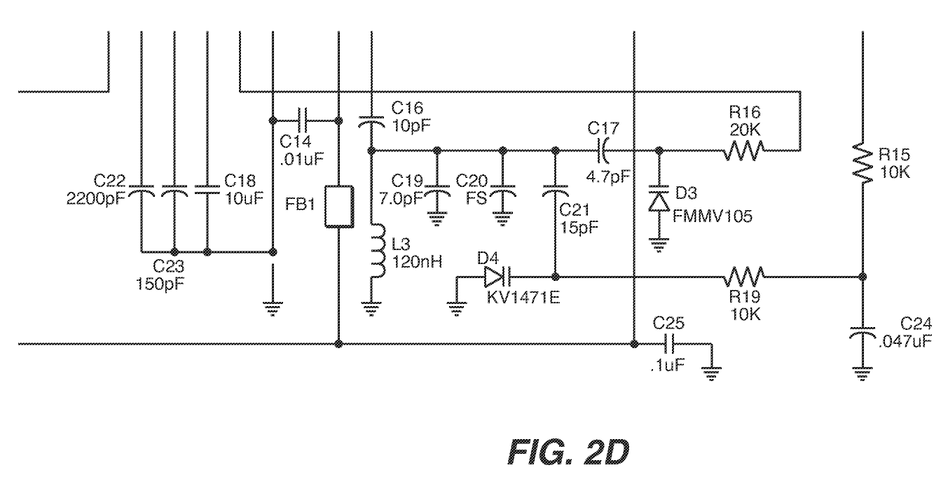

Referring next to FIG. 2 (partitioned into FIGS. 2A-2D for clarity), there is shown a circuit diagram of a transmitter platform which hosts the claimed auto-off/auto-on circuit as used in the preferred embodiment. Audio signals from an external source such as a CD player, cassette tape player, MP3 player, etc., enter the circuit at P1 via a standard 3.5 mm three conductor audio cable and are attenuated, AC coupled, and routed to the right and left audio input pins (1 and 22) of the FM transmitter chip. Each channel is routed through a 50 uS pre-emphasis network, a limiter circuit to prevent over-deviation of the transmitter by excessive audio levels, and a 15 kilohertz (KHz) lowpass filter network to remove undesired spectral components outside the audio range. The processed audio signals are then fed to the stereo multiplexer. This circuit does the left-right channel subtraction, modulates a 38 KHz subcarrier provided by the PLL with this signal, and divides the 38 KHz source by two (2) to generate a 19 KHz pilot, and outputs the gain-scaled composite signal on pin 5.

The transmit chain consists of an on-chip phase-locked oscillator with an external AC-coupled tank circuit consisting of L3, C17, C19, C20, C21, and varactor diodes D3 and D4. The oscillator frequency is sampled on-chip and divided by a programmable divider down to approximately 100 KHz, where it is compared with a 100 KHz reference signal derived from a crystal reference oscillator operating at 7.5 MHZ. The result of this phase comparison is output from pin 7 to an external loop filter consisting of Q1, C10, C11, C24, R9, and R15, having a bandwidth of about 14 Hz. The DC output of the loop filter is an error voltage proportional to the difference of the divided down oscillator frequency and the divided down reference signal, and is applied to varactor D4, coupled to the oscillator tank circuit by C21, thus controlling the oscillator frequency. Capacitor C20 is selected during manufacture to center the oscillator in the desired range, assuring that frequency lock is maintained over the entire operating voltage and temperature range.

Channel selection is performed by changing the divide ratio of the programmable divider in the oscillator chain. Slide switch SW1, the diode decoding matrix formed by D1 and D2, and the on-chip decoding of signals D0-D3 (pins 15-18) allow the selection of four (4) channels in the range of 88.1 to 107.9 MHZ.

The composite stereo baseband signal from pin 5, above, is routed through R16 to varactor diode D3, which is coupled to the oscillator tank circuit by C17. The change in capacitance of this diode caused by the varying composite baseband signal causes small changes in the oscillator frequency, thus frequency modulating the oscillator with the composite signal. Due to the very narrow loop filter bandwidth, the PLL is unable to track out the modulation. A separate varactor diode was used for the modulation path to improve modulation linearity from channel to channel, assuring constant deviation over the operating range.

Primary power for the circuit is can be provided by a CR2 3V lithium battery or other DC power source. As useful power can be obtained from the battery down to about two (2) volts, and circuit operation is degraded below about 2.8 volts, a switching regulator is used to transform the varying battery voltage to 3.75 volts into the regulator filter. This regulator is a PWM type switcher optimized for efficiency, with the switching frequency varying with battery voltage.

Two important features of the disclosed circuit are the effects of capacitance and “pinch-off.” In the circuit as shown, where Q2 is a P-channel field effect transistor (MOSFET), as the drain voltage (V_{D}) within the circuit increases, so does the drain current (I_{D}), up to a certain level-off value. This is true as long as the gate voltage is constant and is not too large. As the gate voltage continues to increase (positively, since this is a P-channel device) a depletion region begins to form on the channel. Charge carriers cannot flow in this region because they must pass through a narrow channel. Ultimately, if the gate voltage becomes high enough, the depletion region will completely obstruct the flow of charge carriers; this is referred to as pinch-off. Capacitance, on the other hand, impedes the flow of alternating current (AC) charge carriers by temporarily storing the energy as an electric field.

In the auto-off mode, Q2 is pinched off, with the capacitor labeled C29 charged to the battery voltage. Comparator U3, which is always on, senses the presence of audio peaks, which when detected drive the output of U3 low, discharging C29, thus turning on Q2 which supplies power to the regulator. The comparator's non-inverting input is biased around eighty-five (85) mV, while the inverting input is AC coupled to the audio source. Whenever an audio peak (low) drops U3-4 below its eighty-five (85) mV threshold, U3-1 goes low, discharging C29, which has been slowly accumulating a charge through R23. For example, should a period of about seventy (70) seconds go by without any audio pulses discharging C29, it will approach the battery voltage, pinching off Q2. With the input supply cut off, the regulator output drops to zero (0) volts. In this mode, battery drain is about five (5) microamperes.

The auto-on circuit functions in a similar fashion to the auto-off circuit, and preferably has a low current LED on the housing 12 of the transmitter 10 to indicate that the unit is on. Comparator U3 is powered directly off the battery, so it is on all the time. Current drain, in the off-state, is approximately 5 microamperes. As the normal on-current with a new battery is about 22 milliamperes, this means that the off-state current has virtually no effect on battery life.

The positive input to the comparator is biased for a threshold of about 85 millivolts via R21 and R25. In the off-state, capacitor C29 has charged up to the battery voltage through R23, holding the gate of FET Q2 at the battery voltage thus pinching off the current path to U2-1. The inverting input of the comparator is at zero (0) volts, keeping the output on U3-1 essentially open due to the open drain output. In this mode, the trickle current paths are the quiescent current of U3, the bias divider of R25 and R21, and the leakage current of capacitor C29.

When the transmitter 10 is connected to an active audio source, R14 and C30 conduct a sample of the audio to U3-4, the inverting input of the comparator. R28 provides a discharge path to prevent the build-up of a bias across C30 due to leakage currents from the comparator input. When the audio signal exceeds the voltage on U3-3, the comparator output swings low, discharging capacitor C29 through R27, a current limiting resistor. When C29 discharges, the gate of Q2 drops below its pinch-off threshold, turning the device on and supplying current to the regulator U2. The device is now on.

Capacitor C29 will be slowly charged through R23, but rapidly discharged by U3 whenever the audio signal swings above the comparator threshold. Current values define a power-off time of just over thirty (30) seconds, that is, if the audio source is quiet for more than about thirty (30) seconds, the device will shut off.

In a practical application of the circuit, the comparator polarity could be turned around, or reversed, such that it was sensing the positive going peaks to discharge the capacitor. Practical application of this circuit has been made possible by the recent availability of ultra low-power, low voltage comparators. Among the devices identified to work in this application are the National Semiconductor LMC7221, the Micrel MIC7221, Maxim's MAX986, MAX990, MAX994, and TI's TLC372, TLV1391, and TLV3401.

The LED used is a very low current, high intensity device made by Hewlett-Packard. Biasing this device with a forward current of 600-800 microamperes, provides more than adequate intensity; whereas, a conventional LED would be biased in the 10-20 millampere range for a similar intensity.

Another improvement implemented in this design is the addition of C31 in parallel with L1. The value of C31 is selected to parallel resonate L1 at 89 MHZ, providing a significantly higher impedance path to ground for the transmitter RF output coupled to the audio cable shield. Additionally, the combined auto-on/auto-off circuit is ideally suited for use with a power amplifier (power-amp) that can be used to boost the signal when re-transmitting the signal to one or more remote/additional receivers. The power amplifier, also called a “final amplifier” as it relates to the several stages of RF or general signal amplification, boosts the signal strength to the level necessary for reception.

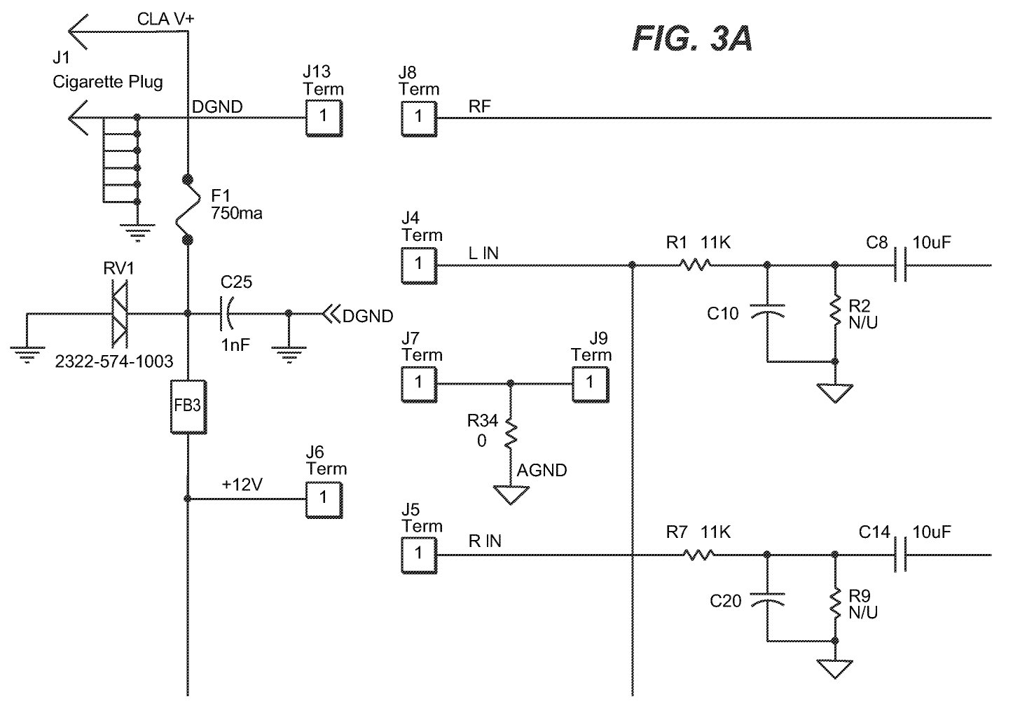

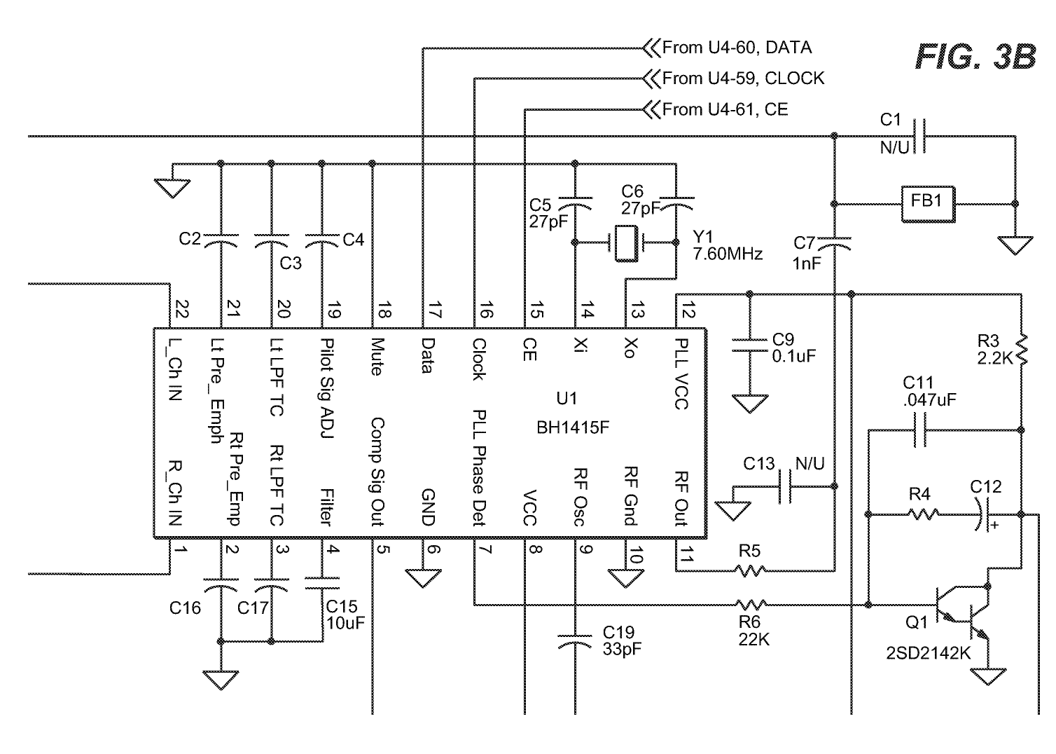

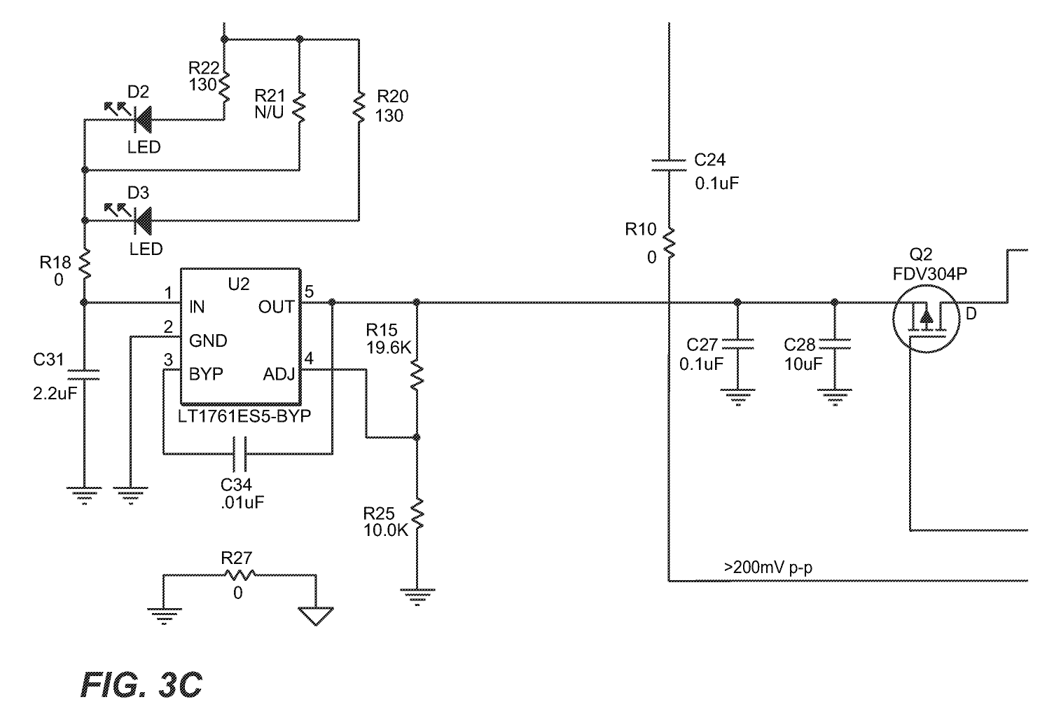

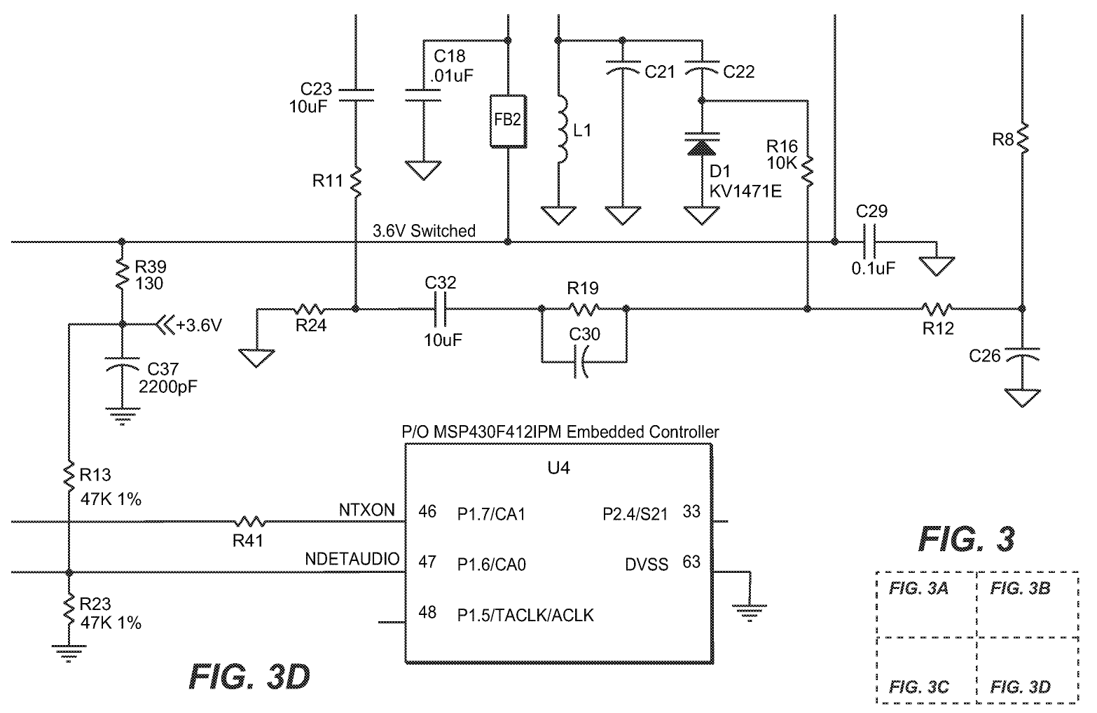

Referring now to FIGS. 3A-3D, an additional alternative embodiment of the power-saving function of the present invention is shown. Note that the schematic includes, as its primary part, the transmitter circuits of a battery-powered transmitter. These circuits are typical of low-power low-current-drain transmitters current in the art. The power-saving circuitry of the present invention is seen in the power supply circuits, the components for which are found in the bottom third of the schematic drawing.

Still referring to FIGS. 3A-3D, it can be seen that a direct-current power source (such as a 12V battery) provides power, via resistor R20 and then through light-emitting diode (LED) D3 and resistor R18, to the input (pin 1) of regulator chip U2. A parallel path is also used to provide, via resistor R22, LED D2 and resistor R18, current to the input (pin 1) of regulator chip U2. Capacitor C31 provides filtering of the input voltage. Capacitor C34 provides a bypass capacitance.

Regulator chip U2 is set (via the values of resistors R15 and R25) to regulate its output voltage to approximately +3.6V. Capacitors C27 and C28 provide filtering of the output voltage of regulator chip U2.

The output (pin 5) of regulator chip U2 provides source current to the source terminal of MOSFET Q2. The drain terminal of MOSFET Q2 provides the current source to all of the transmitter circuits.

The gate of MOSFET Q2 is connected to the NTXON (pin 46) output of embedded controller U4 via resistor R41. The gate of MOSFET Q2 is also connected to the positive terminal of capacitor C33. When capacitor C33 is charged to near the positive supply voltage, it causes MOSFET Q2 to pinch off current to its output drain terminal, thus turning off power to the transmitter circuits. Capacitor C33 slowly charges from the regulated +3.6V supply via resistor R14. Resistor R14 is very high to create a very long RC time constant with capacitor C33.

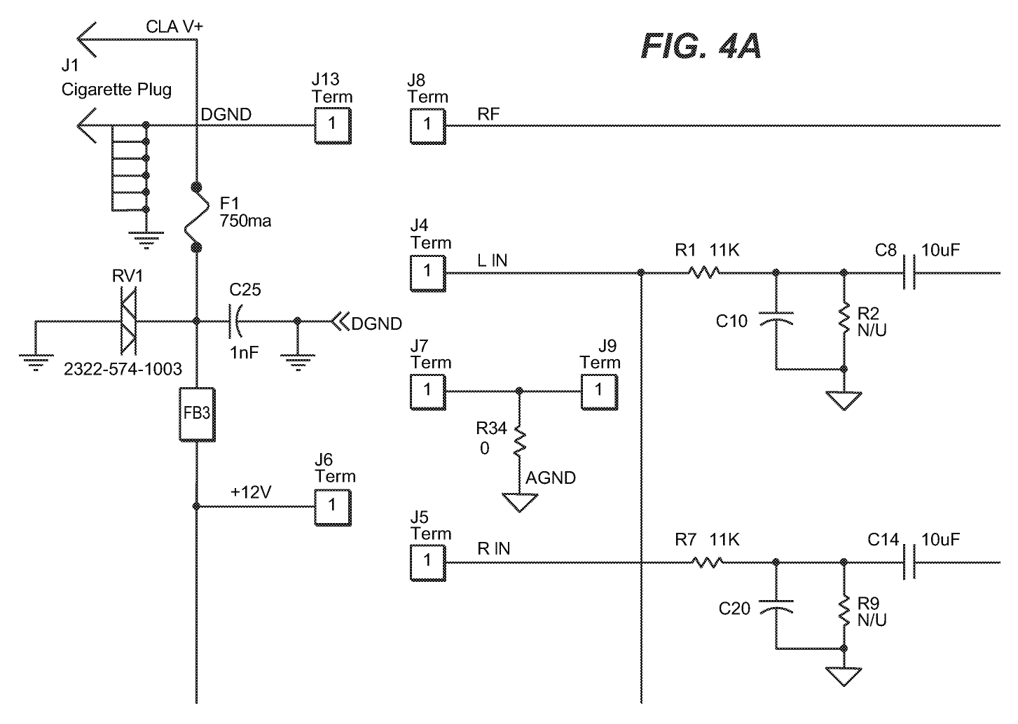

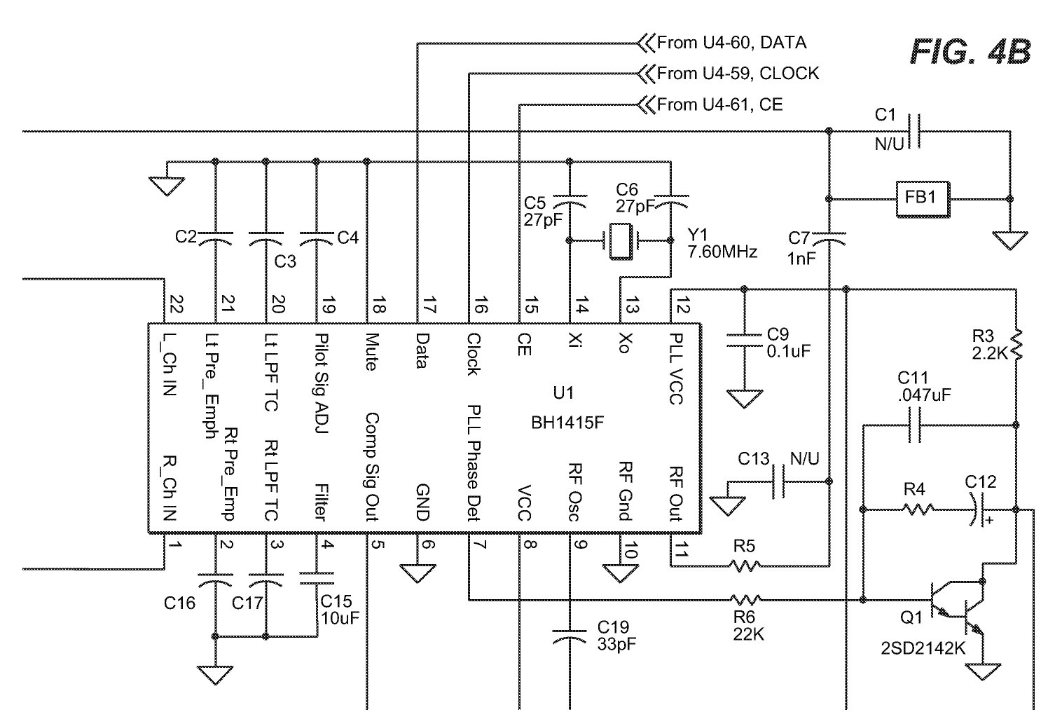

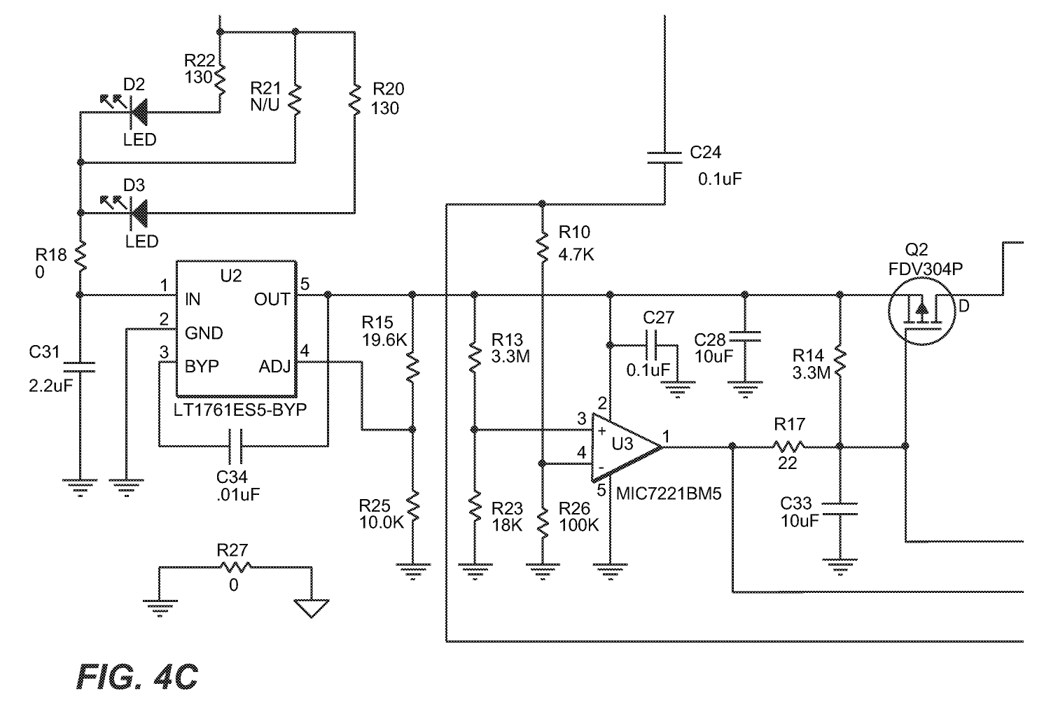

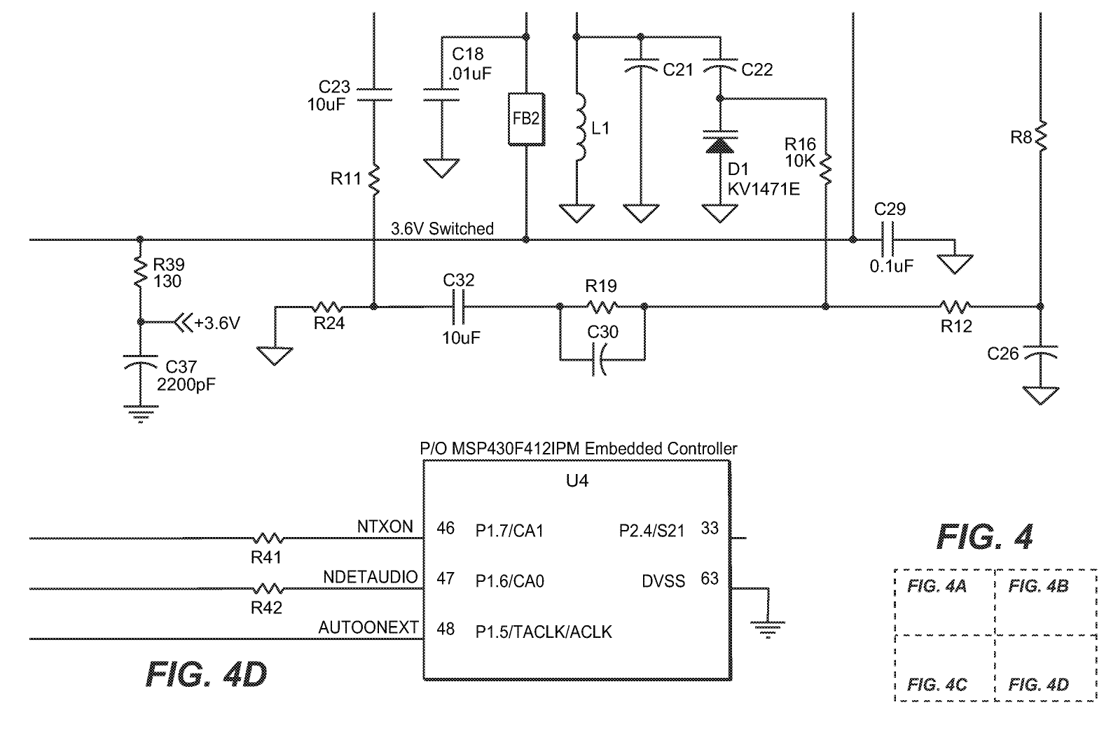

Still referring to FIGS. 3A-4D, comparator U3 receives +3.6V power directly from the output of regulator chip U2. The non-inverting input (pin 3) of comparator U3 is biased to a value of approximately 1 millivolt through the values of resistors R13 and R23. The inverting input (pin 4) of comparator U3 receives an audio input via capacitor C24 and resistor R10. The inverting input (pin 4) of comparator U3 also receives the voltage provided by the AUOTONEXT output (pin 48) of embedded controller U4 via resistor R10.

In the case where the voltage provided by the AUOTONEXT output (pin 48) of embedded controller U4 via resistor R10 is greater than the bias value of comparator U3, the output (pin 1) of comparator U3 is pulled to near ground, thereby rapidly discharging capacitor C33 through R17, thus causing MOSFET Q2 to allow current flow to its output drain terminal. This causes the transmitter circuits to turn on (or remain on).

In the case where the AUOTONEXT output (pin 48) of embedded controller U4 is floated (neither pushed high, nor pulled low, but providing a very high input resistance), the actions of comparator U3 are dependent on the presence or absence of audio signal at the inverting input (pin 4) of comparator U3.

When audio is present on the inverting input (pin 4) of comparator U3, the output (pin 1) of comparator U3 is pushed to near ground, thus rapidly discharging capacitor C33 via resistor R17. This causes MOSFET Q2 to allow current flow to its output drain terminal. This causes the transmitter circuits to turn on (or remain on).

When comparator output (pin 1) is pulled to near ground, the NDETAUDIO input (pin 47) of embedded controller U4 is pulled to near ground through resistor R42. When this occurs, firmware in embedded controller U4 detects and records the event. Once such an event is recorded, the firmware in embedded controller U4 watches for the event where the NDETAUDIO input (pin 47) of embedded controller U4 is pushed above a voltage threshold through resistor R42. This voltage threshold is less than the positive voltage required to cause MOSFET Q2 to pass current. When this second event is detected, the NTXON output (pin 46) of embedded controller U4 is pulled low (near to ground), rapidly draining capacitor C33 through resistor R17, thereby keeping the gate of MOSFET Q2 low and thus keeping power supplied to the transmitter circuits.

This condition is maintained while a positive voltage is provided at the AUTOONEXT output (pin 48) of embedded controller U4. This positive voltage is fed, via resistor R10 to the inverting (pin 4) input of comparator U3. This immediately forces the output (pin 1) of comparator U3 to near ground, thus rapidly discharging capacitor C33, via resistor R17. This condition causes MOSFET Q2 to continue to provide power to the transmitter circuits. Once the positive voltage is provided at the AUTOONEXT output (pin 48) of embedded controller U4, embedded controller U4 floats its NTXON output, and starts an internal timer that measures the amount of time elapsed since the absence of audio was detected. If a predetermined amount of time has elapsed (70 seconds, for example), the AUTOONEXT output (pin 48) of embedded controller U4 is floated, so if no audio is then present, the inverting input (pin 4) of comparator U3 is pulled to ground potential through resistor R28. When this occurs, the output (pin 1) of comparator U3 is again pushed to near the supply voltage, charging capacitor C33 through resistor R17, thus causing MOSFET Q2 to pinch off the current to its output drain terminal (turning off the transmitter circuits). When this happens, the NDETAUDIO input (pin 47) of embedded controller U4 is pulled to near ground through resistor R42. When embedded controller U4 detects this event, it resets and waits to detect the condition where audio is once again present.

If audio is present when the internal timer of embedded controller U4 reaches its predetermined time limit, when the AUTOONEXT output (pin 48) of embedded controller U4 is floated, the inverting input of comparator U3 detects the audio, thereby continuing to hold its output (pin 1) near ground potential, keeping capacitor C33 discharged, thus causing the gate of MOSFET Q2 to remain low and allow current to flow to its output drain terminal. This keeps power supplied to the transmitter circuits. In this condition, embedded controller U4 detects that its NDETAUDIO input (pin 47) was never pulled high after the AUTOONEXT output (pin 48) of embedded controller U4 was floated. This condition causes the firmware in embedded controller U4 to begin watching once again for the absence of audio.

By this description it can be seen that the embodiment of the invention shown in FIGS. 4A-4D provides the power-saving function of the present invention by keeping power turned off to the transmitter circuits until audio is present from an audio source. When audio is present, the transmitter circuits are turned on, and when the audio disappears, after a predetermined delay, the transmitter circuits are automatically turned off to save battery power and prevent unnecessary RF transmissions.

Now referring to FIGS. 4A-4D, another alternative embodiment of the power-saving function of the present invention is shown in a schematic form. Note that the schematic includes, as its large part, the transmitter circuits of a battery-powered transmitter. These circuits are typical of low-power low-current-drain transmitters current in the art. The power-saving circuitry of the present invention is seen in the power supply circuits whose components can be seen in the bottom third of the schematic drawing.

Still referring to FIGS. 4A-4D, it can be seen that a direct-current power source (such as a 12V battery) provides power, via resistor R20 and then through light-emitting diode (LED) D3 and resistor R18, to the input (pin 1) of regulator chip U2. A parallel path is also used to provide, via resistor R22, LED D2 and resistor R18, current to the input (pin 1) of regulator chip U2. Capacitor C31 provides filtering of the input voltage. Capacitor C34 provides a bypass capacitance.

Regulator chip U2 is set (via the values of resistors R15 and R25) to regulate its output voltage to approximately +3.6V. Capacitors C27 and C28 provide filtering of the output voltage of regulator chip U2.

The output (pin 5) of regulator chip U2 provides source current to the source terminal of MOSFET Q2. The drain terminal of MOSFET Q2 provides the current source to all of the transmitter circuits.

The gate of MOSFET Q2 is connected to the NTXON (pin 46) output of embedded controller U4 via resistor R41. When the output on pin 46 of embedded controller U4 is pushed high (near to the positive supply voltage), it causes MOSFET Q2 to pinch off current to its drain terminal, thereby turning off power to the transmitter circuits and halting the transmission of RF signals. When the output on pin 46 of embedded controller U4 is pulled low (near to ground), it causes MOSFET Q2 to allow current to flow to its drain terminal, thereby turning on power to the transmitter circuits and starting the transmission of RF signals.

The NDETAUDIO input (pin 47) of embedded controller U4 is a comparator input that detects the presence of an audio signal arriving via capacitor C24 and resistor R10. Pin 47 of embedded controller U4 will follow either the voltage on C33 when U3 is in open drain mode or shorted to ground when comparator U3 trips. The positive input of comparator U3 is biased at +5.45 mV by the values of resistors R13 and R23.

When audio is present on pin 48 of embedded controller U4, its internal comparator output indicates so, thereby causing internal firmware to pull NTXON (pin 46) of embedded controller U4 to near ground. When this occurs, the gate of MOSFET Q2 is pulled low, allowing current to flow to its drain terminal, thereby turning on the transmitter circuits.

When audio is no longer detected as present on the NDETAUDIO input (pin 48) of embedded controller U4, embedded controller U4 starts an internal timer, measuring the duration of the absence of audio on the input pin. If the internal timer reaches a predetermined duration (70 seconds, for example), embedded controller U4 pushes its NTXON output (pin 46) to near the positive supply voltage. This results in the gate of MOSFET Q2 being pushed high, pinching off the current flow to its drain terminal, thus turning off the transmitter circuits. If audio reappears on the NDETAUDIO input (pin 47) of embedded controller U4 before its internal time reaches a predetermined duration, the timer is deactivated, and the NTXON output (pin 46) of embedded controller U4 remains pulled to near ground, thus leaving MOSFET Q2 in the mode of providing current to the transmitter circuits. It is important to note that the microcontroller may need to only sample only as fast as once per second over the timeout period of 70 seconds. This is because over this period, the microcontroller will sample the audio levels roughly 70 times. Given that the audio signal is ac-coupled, it is very likely that one of the 70 samples will exceed the software defined threshold. An hence, even if a single sample exceeds the threshold, the turn on period will be extended for another 70 seconds. Similarly, in order for the microprocessor to signal an auto-off by raising pin 46, is to sample 70 consecutive audio signals that is close to zero. It is important to note that a 70 Hz or a multiple there of sampled at precisely the correct phase will also yield an auto-off condition. However, this is such an unlikely event that this corner case may be ignored.

By this description it can be seen that the embodiment of the invention shown in FIG. 3 provides the power-saving function of the present invention by keeping power turned off to the transmitter circuits until audio is present from an audio source. When audio is present, the transmitter circuits are turned on, and when the audio disappears, after a predetermined delay, the transmitter circuits are automatically turned off to save battery power and prevent unnecessary RF transmissions.

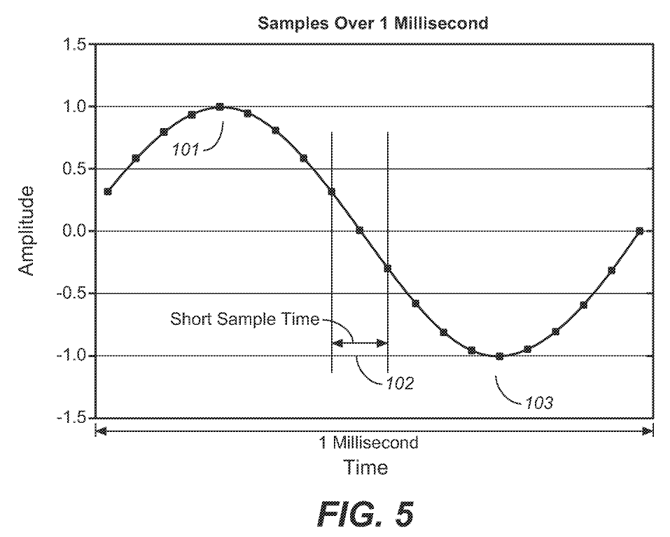

Referring next to FIG. 5, the preferred method of carrying out the auto-off implementation of the present invention is to use a continuous audio level sensing mechanism by continuously digitizing the audio samples. This continuous audio level sensing mechanism is essentially an analog-to-digital converter (“ADC”) that samples the audio at or above Nyquist frequency. A sufficiently long sample length can be set and used to determine the absolute maximum value of that period of time. Generally, the number of samples that must be taken is only what is needed to find the maximum/minimum values of a tone to be sensed. For example, if it is desired to sense a single 100 Hz tone as in FIG. 5, it will be necessary to sample longer than 10 milliseconds of audio at the audio sampling rate. If a reduction in timing precision in the sensing can be tolerated, the sample length may be reduced even longer, as in the short sample time 102. The end effect of reducing the sampling time will be a reduction of dynamic range of the resulting value since a short sensing time will not allow the slowest waveforms to fully swing from one peak 101 to another peak 103.

While calculating the absolute maximum audio level, storage of only two variables is required, as it is only necessary to store the maximum peak value 101 or minimum peak value 103 of the audio sample. At the end of sensing the sample length, the absolute difference is taken by subtracting the minimum value from the maximum. This value can then be used as an indicator for the maximum audio level during that period of time. When the absolute difference value is below a certain threshold for a period of time, the device can then initiate a power-down sequence.

In order to detect the presence or absence of audio, it is also possible to choose to sample only the positive half or negative half, or some other portion of the waveform. In most cases, the micro controller unit (“MCU”) may only be able to sense the positive half only since an internal ADC to the MCU will not be able to sense negative swings natively.

This method, while very accurate, will require an ADC to run at nearly 48 kHz for CD quality audio signals and will be taxing for an MCU to calculate such a value at all times. However, the audio information may be provided and made available internally within a codec in the MCU, and this value can easily be determined simply by monitoring the audio input values. This information can then be supplied as a read register in the interface to the controlling CPU. In contemporary microprocessors, such interfaces will take the form of either an inter-integrated circuit (“I²C”) or a serial peripheral interface bus (“SPI”).

In a system where a dedicated piece of hardware is not available for use in determining the audio level, a simple method using a comparator external or internal to an MCU can be employed instead. Using a comparator is more favorable since it is a simpler circuit and will likely cost less in terms of system implementation. In the context of MCU peripheral usage, using a comparator is also preferable, since it will likely draw less power in its usage.

Additionally, an ADC may be used as if it is a comparator by feeding the audio signal through a bypass capacitor into the MCU directly. The MCU may sense the audio signal single ended and will only receive the positive half of the wave at the sensing input. Sampling at a slow rate such as 1 Hz will allow for the ADC to ‘catch’ a signal by chance that is over a threshold value. If the value is over a threshold then the system can extend the timeout period.

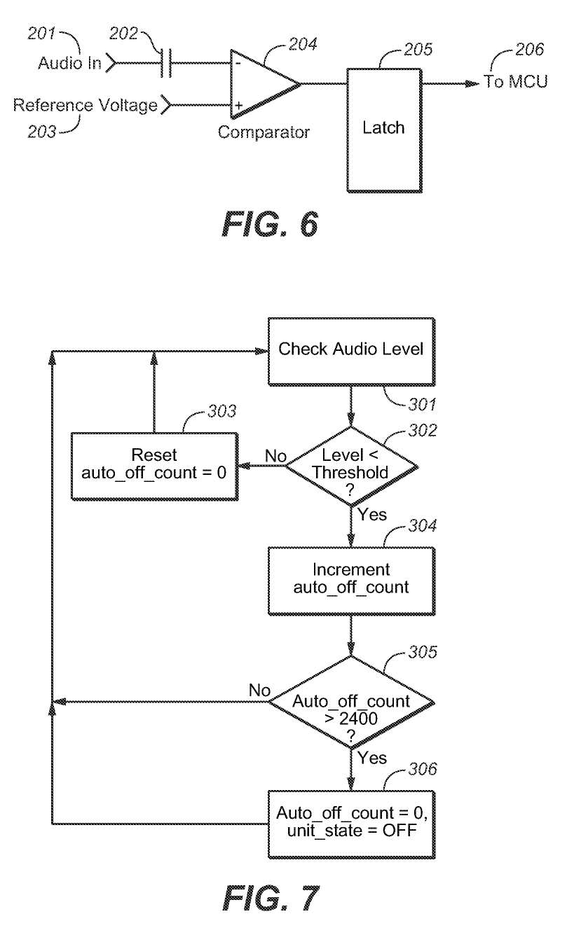

Referring next to FIG. 6, to use a comparator to sense the absolute maximum audio level 201, one of the audio channels is AC coupled via a capacitor 202 to the comparator 204 without loading the audio signal. The comparator will then signal true whenever the input value is below the compared value of the reference voltage 203. The output of comparator 204 may be optionally sent via latch 205 for the MCU 206 to read the value. Since audio typically has signal content as high as 20 kHz, one may be lead to believe that one must sample at such a high rate. However, this is not the case, because it is possible to sample at a much slower rate and still achieve satisfactory results. The reasons follow.

A slower rate, e.g., a 100 Hz sampling rate, will function satisfactorily as long as the input audio content is not composed of only multiples of such frequencies and is not sampled at exactly the wrong phase so as to cause the input sample to read below the threshold at all times. Since such an event is highly unlikely in typical consumer audio content, it is possible to disregard such rare occurrences. But to increase the robustness of the algorithm, the sampling can take place over the duration of a second or more so as to allow the audio content to change enough to register with the reduced rate sensing.

Furthermore, one can also tie the comparator output to an MCU interrupt such that sampling can be eliminated altogether. This is best used for the device wake up function because the unit will wake up once the comparator threshold is exceeded either in the positive or negative direction. In contrast, if it is not desired to have the system power down when the sensed voltage is momentarily below the threshold as may be the case sometimes.

In an actual implementation of the present invention, a pair of transceivers is employed, each with its own MCU. One of the transceivers will be in transmit mode and in that mode is able to transmit to multiple units of the same device. [This kind of unit is described in detail in co-pending U.S. Utility patent application Ser. No. 11/721,319, which is a Section 371 filing of International Patent Application, International Publication Number WO 101218 A2, incorporated in its entirety by reference herein.] Each unit is able to switch to either transmit or receive readily. When in the transmit mode, the device will digitize an audio signal and send the audio data through an RF module. One of many receiving units will then receive the data via another RF module and reconstruct the analog waveform and output to a headphone amplifier.

To accomplish auto-off using audio sensing, the RF module is setup in transmit mode to interrupt the processor at a predefined interval with audio threshold information. The interval set is roughly 125 ms or 8 Hz. Any amount of timeout can be set by counting the number of times the audio level is below a certain threshold and subsequently resetting the count to zero if the sampled value is ever above the threshold level.

The internal mechanism in the RF module setup in transmit mode is set to find the maximum and minimum level within a predetermined time frame and creates an absolute maximum value internally. The value is used by a system MCU by monitoring that value and counting the amount of counts the audio is below the threshold. For example, 2400 counts equates to roughly five minutes of no audio.

When the audio is below the threshold for a set amount of time, the system will flag the unit state to the off mode. The system will sense this flag and enter the power-off mode procedure. Hence, auto-off in this context is triggered by a low audio level in the transmitter.

Auto-off in the receiver is accomplished in a different manner. Due to hardware limitations in the RF module, the receiver is unable to sense audio levels coming from the transmitter. Instead, a RF synchronization flag is used. Essentially, this method relies on the transmitter to first auto-off, which allows the receiver to sense a loss in RF synchronization. A time out period of two minutes is set so as to sense the auto-off of the transmitter. Thus, from the initial audio turning off to the turn-off time of a receiver is actually five plus two (5+2) minutes. This example illustrates how alternative methods, i.e. the loss of an RF synchronization, can be used to signal a device to switch into a low-power mode. In this case, a loss of RF synchronization can occur due to three different causes: (1) a transmitter automatically turned off due to five minutes of low audio; (2) the intermittent loss of RF synchronization due to a low link quality; or (3) an out of range condition where the receiver and transmitter unit are too far from one another.

To prevent the second case from creating a false auto-off, the receiver must wait long enough after the loss of RF synchronization before commencing the auto-off sequence. Typically, this RF synchronization timeout will range from a few minutes to guard against long drop outs being misinterpreted as permanent loss of RF synchronization.

Referring now to FIG. 7, there is shown a basic software flow diagram used to flag an auto-off event. Various means can be used to check the audio level as described previously. The check is done at step 301 and is compared 302 to a set threshold level. The threshold level is chosen to be slightly above the noise level so that the noise level will not register a false positive in the logic. If the level is above the threshold then the counter is reset back to zero at step 303. On the other hand, if the level is below the threshold, then the counter will start incrementing at step 304. The counter is then compared to a set value that will determine the auto-off time at block 305. If the counter has not yet exceeded the auto-off count, it will keep on counting until it does. If for any single instance the counter is above the threshold, the counter value will reset back to zero and the sequence will start over. On the other hand, if the counter exceeds a certain amount, 2400 in this diagram, which represents five minutes, an auto-off sequence will be initiated at block 106 by use of a system flag.

The above disclosure is sufficient to enable one of ordinary skill in the art to practice the invention, and provides the best mode of practicing the invention presently contemplated by the inventor. While there is provided herein a full and complete disclosure of the preferred embodiments of this invention, it is not desired to limit the invention to the exact construction, dimensional relationships, and operation shown and described. Various modifications, alternative constructions, changes and equivalents will readily occur to those skilled in the art and may be employed, as suitable, without departing from the true spirit and scope of the invention. Such changes might involve alternative materials, components, structural arrangements, sizes, shapes, forms, functions, operational features or the like.

Therefore, the above description and illustrations should not be construed as limiting the scope of the invention, which is defined by the appended claims.

What is claimed as invention is:

1. An apparatus for sensing the absence of audio in a consumer electronic device and automatically placing the electronic device in a low power mode, said apparatus comprising:
at least one electronic audio device;
an audio level sensing mechanism incorporated into said electronic audio device which continuously samples audio input samples to identify the maximum value and minimum value of a sensed tone and at the end of sensing the audio input sample, an absolute difference value is calculated by subtracting the minimum value from the maximum value, and the absolute difference value is used as an indicator for the maximum audio level during that period of time, and wherein when the value of the absolute difference is below a predetermined threshold for a period of time, said electronic audio device initiates a power-down sequence.

2. An apparatus for sensing the absence of audio in a consumer electronic device and automatically placing the electronic device in a low power mode, said apparatus comprising:
at least two transceivers, each of said transceivers having a micro processor unit (“MCU”) and an RF module including an RF synchronization flag, wherein each transceiver can switch between a transmit mode and a receive mode, and when in a transmit mode each transceiver will digitize an audio signal and send the digitized audio data through said RF module, and wherein at least one of said at least two transceivers in receive mode will then receive the digitized audio data via its RF module and reconstruct the analog waveform and output to a headphone amplifier;
an audio level sensing mechanism incorporated into each of said at least two transceivers which continuously samples audio input samples to identify the maximum value and minimum value of a sensed tone and at the end of sensing the audio input sample, an absolute difference value is calculated by subtracting the minimum value from the maximum value, and the absolute difference value is used as an indicator for the maximum audio level during that period of time, and wherein the transceiver in transmit mode will initiate a power-down power saving sequence when the value of the absolute difference is below a predetermined threshold for a period of time, and said transceiver in receive mode will initiate a power-down power saving sequence when RF synchronization is lost and is unable to sense audio levels coming from said transceiver in transmit mode, thereby providing battery savings in each of said transceiver in transmit mode and said transceiver in receive mode.
